(19) United States
(12) Patent Application Publication
(10) Pub. No.: US 2011/0058411 A1
(43) Pub. Date: Mar. 10, 2011

(54) PHASE CHANGE MEMORY SYSTEM HAVING WRITE DRIVER

(75) Inventor: Woo Jin RIM, Ichon-si (KR)

(73) Assignee: HYNIX SEMICONDUCTOR INC., Ichon-si (KR)

(21) Appl. No.: 12/643,490

(22) Filed: Dec. 21, 2009

(30) Foreign Application Priority Data
Sep. 4, 2009 (KR) 10-2009-0083341

(51) Int. Cl. G11C 11/00

(52) U.S. Cl. 365/163; 365/148

(57) ABSTRACT

A phase change memory system capable of gradually reducing current at the time of writing set data by using a small number of control circuits while occupying a small dimension is disclosed. The phase change memory system includes a memory cell array including a plurality of memory cells, each including a phase change material which is changed into a set or reset state depending on the amount of current, and a write driver supplying current corresponding to a set or reset state to a selected memory cell of the memory cell array. The write driver includes a slow quenching unit including an analog circuit supplying current slowly decreased in the memory cell array.

### CROSS-REFERENCE TO RELATED PATENT APPLICATION

The present application claims priority under 35 U.S.C §119(a) to Korean Application No. 10-2009-0083341, filed on Sep. 4, 2009, in the Korean Intellectual Property Office, which is incorporated herein by reference in its entirety as if set forth in full.

### BACKGROUND

1. Technical Field

Various embodiments of the present disclosure generally relate to a nonvolatile memory system and, more particularly, to a phase change memory system having a write driver.

2. Related Art

Memory devices are generally classified as random access memory (RAM) or read only memory (ROM). RAM is a volatile memory in which inputted information may be erased. ROM is a nonvolatile memory in which inputted information is stored when power is interrupted. Presently, RAM may comprise a dynamic random access memory (DRAM) and a static random access memory (SRAM) and ROM may comprise a flash memory.

DRAM is advantageous because it has low power consumption and enables random access to the DRAM. A disadvantage to DRAM is that it is volatile and requires a high charge storage ability, which requires a large capacity capacitor. SRAM may be used as, for example, a cash memory. SRAM is advantageous in that it enables random access to the SRAM and its access speed is fast. Disadvantages to SRAMs are its volatility and large size which increase its operating cost. In addition, flash memory is nonvolatile memory, but uses a structure comprising two laminated gates that require a higher operation voltage than power supply voltage. This requires an additional boost-up circuit to create the voltage required for writing and erasing operations. Integration of flash memory, however, is difficult and its operational speed is slow.

Various memory devices have been developed to solve the above-mentioned problems of the conventional memory devices. These devices comprise, for example, a ferroelectric random access memory (FRAM), a magnetic random access memory (MRAM), and a phase-change random access memory (PRAM).

PRAM comprises a phase change material having a high resistance in an amorphous state and a low resistance in a crystalline state. PRAM is a memory device that writes and reads information by using the phase change of the phase change material. This is advantageous because PRAMs have faster operational speeds and higher integration in comparison with flash memory.

A memory cell of PRAM may comprise a switching element connected to a word line, a phase change material that receives heat by the opening and closing of the switching element, and a bit line to write data in the phase change material. PRAM may perform read and write operations like other memory devices. A read operation of PRAM may measure a resistance value written in the phase change material by applying a voltage and current low enough so as not to change a crystalline state of the phase change material.

During a write operation of PRAM, the crystalline state of the phase change material may be varied by current supplied from the bit line, such that data of “1” or “0” is written in the phase change material.

When the phase change material is in the amorphous state, germanium (Ge) atoms constituting the phase change material deviate to one side of the material to be asymmetrically coupled with other atoms as shown in FIG. 1A. Accordingly, the phase change material does not fully achieve covalent bonding. In this state, the phase change material has a comparatively high resistance value and the phase change material is referred to as being in a reset state. The resistance value of the phase change material in the reset state is defined as data “1”.

When the phase change material is in the crystalline state, as shown in FIG. 1B, all Ge atoms are spaced from atoms at a cubic face center by regular intervals such that they achieve symmetrical covalent bonding. Therefore, the phase change material has a comparatively low resistance value and is referred to as being in a set state. The resistance value of the phase change material in the set state is defined as data “0”.

Further, in order to change the phase change material into the amorphous state (reset) state, as shown in FIG. 2, a current supply is quickly reduced (fast-quenched) after applying current at a predetermined level to the phase change material for a predetermined time. The current at the predetermined level may be current which is at a level that is high enough to heat the phase change material to a melting point or higher temperature.

Accordingly, to change the phase change material into the crystalline state, current of a predetermined level is applied to the phase change material for a predetermined time and then a current supply is slowly reduced (slow-quench). As a result, a write driving circuit of the PRAM which is capable of rapidly or gradually reducing current is required.

A known circuit for gradually reducing current is a resistance string circuit. The resistance string circuit comprises a plurality of resistors that are connected to each other in series (IEEE, Journal of Solid State Circuit, “A 90 nm 1.8V 512 Mb Diode-Switch PRAM with 266 MB/s Read Throughput, Kwang-Jin Lee et al, January 2008).

Providing a plurality of resistors arranged in series, as in the resistance string circuit, requires a very large dimension and a plurality of control signals (for example, a program pulse signal, etc.) for selecting different potentials. An auxiliary circuit block for generating the signals is also required to gradually decrease the current, thereby further increasing a dimension of the write driver circuit and consuming large switching power.

### SUMMARY OF THE INVENTION

Accordingly, there is a need for an improved phase change memory system with a write driver that overcomes the problems discussed above. To attain the advantages and in accordance with the purposes of the invention, as embodied and broadly described herein, various embodiments of the invention may provide a phase change memory system comprising a memory cell array comprising a plurality of memory cells, each comprising a phase change material which is changed into a set or reset state, depending on the amount of current, and a write driver that supplies current corresponding to a set or reset to a selected memory cell of the memory cell array. The write driver may comprise a slow quenching unit comprising, for example, an analog circuit that supplies current that is slowly decreased in the memory cell array.

In another aspect, a phase change memory system comprises: a memory cell array comprising phase change memory cells comprising a plurality of word lines, a plurality of bit lines, and a write driver comprising a set/reset pulse generator that may be electrically connected to the plurality of bit lines and a supply current corresponding to predetermined data to the memory cell array The set/reset pulse generator may generate a pulse for generating current that may be transmitted to the selected phase change memory cell array and comprise a buffer circuit unit that buffers output voltage of the set/reset pulse generator. The set/reset pulse generator may also comprise a slow quenching unit that may be, for example, an inverting integrator.

These and other features, aspects, and embodiments are described below in the Detailed Description section. Additional objects and advantages of the invention are set forth in part in the description which follows, and in part are obvious from the description, or may be learned by practice of the invention. The objects and advantages of the invention are realized and attained by means of the elements and combinations particularly pointed out in the appended claims.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention.

FIG. 1A is a diagram showing a lattice state of a phase change material layer in an amorphous state.

FIG. 1B is a diagram showing a lattice state of a phase change material layer in a crystalline state.

FIG. 2 is a diagram showing set and reset pulses of a known phase change memory system.

FIG. 3 is a schematic diagram of an exemplary phase change memory system according to one embodiment of the invention.

FIG. 4 is a detailed circuit diagram showing an exemplary write driver of a phase change memory system according to one embodiment of the invention.

FIGS. 5 and 6 are timing diagrams of signals applied to a phase change memory system according to one embodiment of the invention.

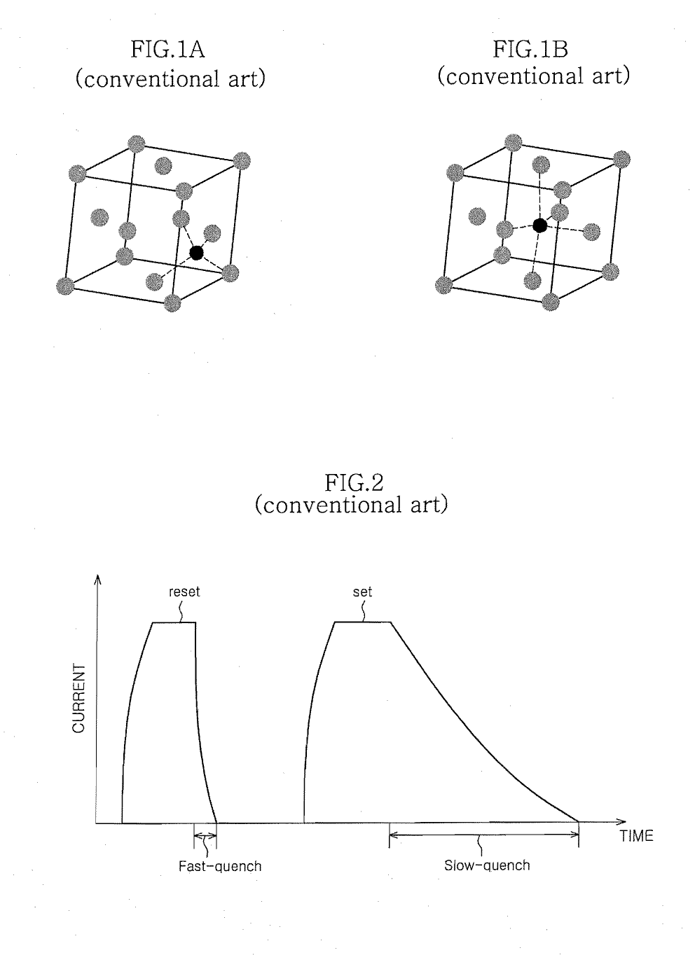

### DETAILED DESCRIPTION OF THE EMBODIMENTS

Advantages and characteristics of the present invention and a method for achieving them will be apparent with reference to embodiments described below in addition to the accompanying drawings. However, the present invention is not limited to the exemplary embodiments described below but may be implemented in various forms. Therefore, the exemplary embodiments are provided to enable those skilled in the art to thoroughly understand the teaching of the present invention and to completely inform the scope of the present invention and the exemplary embodiment is just defined by the scope of the appended claims. Throughout the specification, like elements refer to like reference numerals.

Hereinafter, embodiments of the present invention are described using a phase change random access memory (PRAM). However, it will be apparent to those skilled in the art that the embodiments of the present invention can be applied to all nonvolatile memory devices using a resistor such as, for example, a resistive RAM (RRAM), a ferroelectric RAM (FRAM), and a magnetic RAM (MRAM).

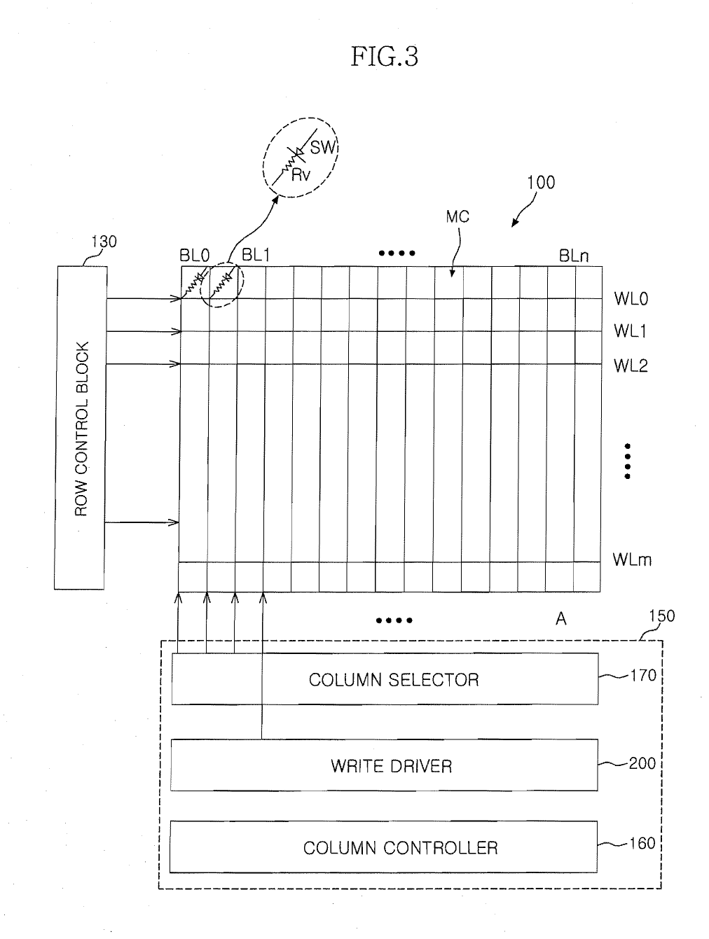

FIG. 3 is a schematic configuration diagram of a phase change memory system according to one embodiment of the invention. Referring to FIG. 3, a phase change memory system 100 may comprise a memory cell array 100, a row control block 130, and a column control block 150 having a write driver 200. The memory cell array 100 may comprise a plurality of nonvolatile memory cells, that is, phase change memory cells (Mc). The memory cell array 100 may comprise a plurality of word lines WL0-WLm that intersect with a plurality of bit lines BL0-BLn. The phase change memory cell Mc may be formed at each intersecting portion between the plurality of word lines WL0-WLm and the plurality of bit lines BL0-BLn. Each phase change memory cell Mc may comprise a variable resistor Rv comprising the phase change material of which a crystalline state is changed depending on a current and a switching element SW that controls the current supplied to the variable resistor Rv. A representative example of the phase change material comprising the variable resistor Rv may be, for example, a chalcogenide material. Further, a vertical-structure diode preferably having a small unit dimension may be used as the switching element, however, other switching elements may also be used.

The row control block 130 may be configured to select a word line connected to the memory cell Mc to be written among the plurality of memory cells Mc. Although the row control block 130 is not shown in the figure, the row control block 130 may comprise a pre-decoder, a row decoder, and the row selector so as to enable the corresponding word line through a row selector by enabling any one of row addresses.

The column control block 150 may be configured to select a bit line BL0-BLn connected to a memory cell Mc to be written. The column control block 150 may comprise a column decoder 160, a column decoder 170, and a write driver 200. The write driver 200 may be configured to supply write current, for example, set current and reset current, to the selected memory cell Mc and is described in more detail below. The column control block 150 supplies the set or reset current generated by the write driver 200 to the bit line selected by a column selector 170 by driving the corresponding column selector 170 by a column selection signal provided from the column decoder 160. It should be apparent to one of ordinary skill in the art that the bit line may be a global bit line.

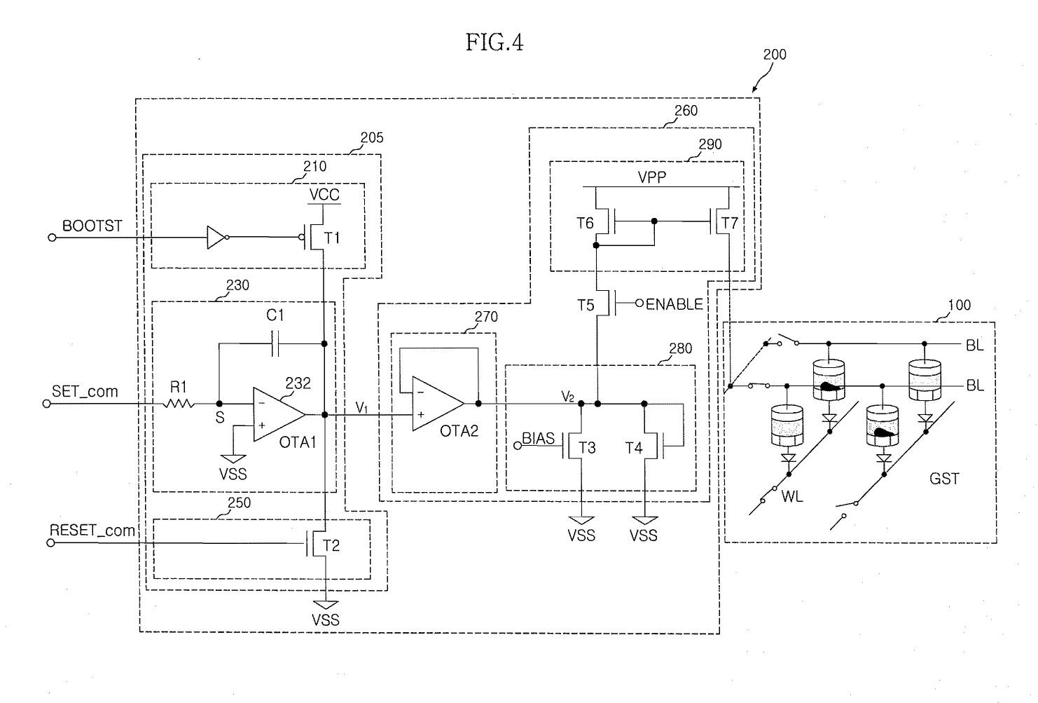

As shown in FIG. 4, the write driver 200 may comprise a set/reset pulse generator 205 and a buffer circuit unit 260. The set/reset pulse generator 205 may comprise a boosting circuit unit 210, a slow quenching unit 230, and a fast quenching unit 250. The boosting circuit unit 210 may be configured to output voltage Vcc at a predetermined level when a boosting signal BOOST is enabled. Voltage at the predetermined level is preferably voltage which generates enough current to change the phase change material. The boosting circuit unit 210 may comprise, for example, an inverter IN that inverts the boosting signal BOOST and a first switching transistor T1 that transfers and outputs the boosting voltage Vcc, depending on an output signal of the inverter IN. The boosting signal BOOST may be, for example, a signal generated by a write enable signal (not shown) and the first switching transistor T1 may be, for example, a wide p-type metal-oxide-semiconductor (PMOS) transistor because of its excellent response speed characteristics, that is, a long channel transistor.

The slow quenching unit 230 may be configured to slow-quench the output voltage Vcc of the boosting circuit unit 210 at the time a set command SET_com is input. The slow quenching unit 230 may comprise an inverting integrator which may be, for example, an analog circuit component. The inverting integrator of the slow quenching unit 230 may comprise a resistor R1, a capacitor C1, and an operation amplifier 232. The operation amplifier 232 has positive/negative inputs (+/−) and the resistor R1 is preferably connected to a negative input terminal (−) of the operation amplifier 232. The capacitor C1 is preferably connected between a node S between the resistor R1 and the operation amplifier 232 and an output terminal of the boosting circuit unit 210. Such a slow quenching unit 230 can slowly discharge output voltage of the boosting circuit unit 210 as time elapses when the set command SET_com is input in the inverting integrator through the resistor R1.

The fast quenching unit 250 may be configured to fast-quench the output voltage Vcc of the boosting circuit unit 210 at the time a reset command RESET_com is input. The fast quenching unit 250 may be, for example, a second switching transistor T2 that is driven in response to the reset command RESET_com. The second switching transistor T2 may be, for example, a wide n-type metal-oxide-semiconductor (NMOS) transistor having excellent response speed characteristics. Therefore, the fast quenching unit 250 may be configured to discharge the output voltage of the boosting circuit unit 210 when the reset command RESET_com is enabled.

Reference numeral V1 represents the output voltage of the set/reset pulse generator 205. The output voltage V1 may be output voltage of the boosting circuit unit 210, output voltage of the slow quenching unit 230, or output voltage of the fast quenching unit 250.

The buffer circuit unit 260 may comprise a buffer 270, a converter 280, and a current mirror 290. The buffer 270 may comprise a voltage follower that buffers the output voltage V1 of the set/reset pulse generator 205. As well known, the voltage follower may be an operation amplifier that amplifies and outputs input voltage. The output voltage V1 of the set/reset pulse generator 205 is input as a positive input thereof and a negative input is connected to the output terminal. The buffer 270 may receive the voltage of the set/reset pulse generator 205 and stabilize the corresponding voltage into voltage V2 at a predetermined level. V2 refers to the output voltage of the buffer 270.

The converter 280 may convert the output voltage of the buffer 270 into a current level. The converter 280 may comprise third and fourth transistors T3 and T4 connected to the output terminal of the buffer 270. The third transistor T3 receives predetermined bias voltage BIAS as gate voltage that is consistently turned on and is connected between the output terminal of the buffer 270 and a ground terminal. A gate and a drain of the fourth transistor T4 are preferably connected to the output terminal of the buffer 270 and a source of the fourth transistor T4 is preferably connected to the ground terminal.

The current mirror 290 mirrors current I1, depending on the voltage level of the converter 280, and supplies mirrored current I2 to the memory cell array 100. The current mirror 290 may comprise fifth to seventh transistors T5, T6, and T7. The fifth transistor T5 is preferably connected between the converter 280 and the sixth transistor T6 and receives enable voltage ENABLE for driving the current mirror 290 as gate voltage. A diode structure, that is, a gate and a source of the sixth transistor T6 are commonly connected to each other and high voltage VPP is received from a drain. The seventh transistor T7 is preferably electrically connected to the gate of the sixth transistor T6 and the high voltage VPP is provided from the drain, and the source is preferably electrically connected to the selected bit line of the memory cell array 100.

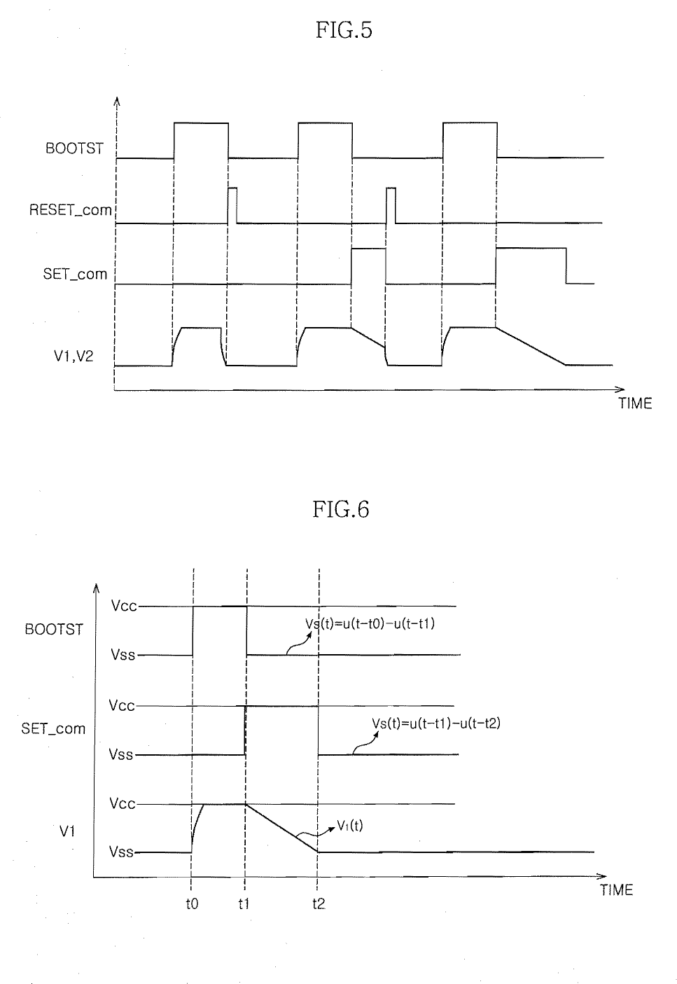

Driving of the phase change memory system having the write driver is now described with reference to FIGS. 5 and 6. First, to change the variable resistor Rv in the crystalline state (data 0) into the amorphous state (data 1), the boosting signal BOOST is enabled to the boosting circuit unit 210 of the write driver 200. Then, the first transistor T1 comprising a wide transistor is rapidly turned on to supply rapidly increased current to the selected memory cell (i.e., phase change material) of the memory cell array 100. Therefore, sufficient energy is provided to the phase change material layer such that many covalent bonds are released and the state of the resistor is changed into the amorphous state.

When the reset command RESET_com of the fast quenching unit 250 is enabled, the second transistor T2 of the fast quenching unit 250 is turned on to discharge the charged output voltage V1 of the set/reset pulse generator 205. As a result, supply of current to the memory cell array 100 is quickly interrupted, such that the phase change material Rv of the memory cell array 100 maintains the amorphous state (RESET).

While the rapidly increased current is supplied, and when the set command SET_com of the slow quenching unit 230 is enabled, the inverting integrator comprising the slow quenching unit 230 is driven. Therefore, the output voltages V1 and V2 of the set/reset pulse generator 205 are generated with slowly decreasing in response to the set command SET_com from the predetermined voltage Vcc. This is described in more detail with reference to FIG. 6.

Referring to FIG. 6, when the set command SET_com is enabled, the output voltage V1 of the slow quenching unit 230 is expressed by an equation calculating the output voltage of the integrator as shown in Equation 1.

$${V}_{1} ( t ) = - \frac{1}{{R}_{1} {C}_{1}} {\int }_{t 1}^{t} {V}_{S} ( t ) d t + {V}_{1} ( {t}_{1} ) ( {t}_{1} < t < {t}_{2} ) \qquad Equation 1$$

When ground voltage Vs of Equation 1 is expressed using a unit step function as shown in Equations 2 and 3, the output voltage V1(t) of the slow quenching unit 230 is acquired as shown in Equation 4.

V_{S}(t)=u(t−t₁)−t(t−t₂)(t₁≦t≦t₂) Equation 2

V_{S}(t)=V_{CC} Equation 3

$${V}_{1} ( t ) = - \frac{1}{{R}_{1} {C}_{1}} {V}_{C C} ( t - {t}_{1} ) + {V}_{C C} ( {t}_{1} < t < {t}_{2} ) \qquad Equation 4$$

In accordance with Equation 4, the slow quenching unit 230 outputs the voltage V1 that is linearly decreasing with respect to time t. A quenching ratio of the output voltage V1 of the slow quenching unit 230 is determined depending on the magnitudes of the resistor R1 and the capacitor C1 of the integrator.

When the output voltage V1 is linearly decreased by using the inverting integrator, the supply of current to the selected variable resistor Rv of the memory cell array 100 (i.e., the phase change material) is slowly decreased such that the phase change material that comprises the variable resistor Rv is slowly cooled through strong covalent bonding. Therefore, the phase change material is in the crystalline state.

Since the operation amplifier that comprises the inverting integrator can generally be implemented by using a small number of MOS transistors, the operation amplifier can be manufactured to have a dimension remarkably smaller than a resistance string. Additionally, the inverting integrator can be operated when only the set command SET_com is input, thus an additional control signal is not required. Therefore, since a circuit block for generating the control signal does not need to be installed, it is possible to reduce a dimension of a peripheral circuit of the phase change memory system.

As described in detail above, the slow quenching unit of the write driver is constituted by the inverting integrator linearly decreasing the voltage. Since the inverting integrator comprises the operation amplifier, the resistor, and the capacitor, the inverting integrator has a comparatively simple circuit structure and a plurality of string type resistors for gradually decreasing the voltage and a plurality of control signals for controlling the plurality of resistors are not required.

In particular, since only the output of the set/reset pulse generator is provided to the converter without supplying a plurality of additional program currents, the number of control signals is remarkably reduced.

Accordingly, it is possible to reduce a circuit dimension of the write driver of the phase change memory system and as a result, it is possible to increase integration density of the phase change memory system.

Throughout the description, including in the claims, the term “comprising a” should be understood as being synonymous with the term “comprising at least one” unless otherwise specified to the contrary.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A phase change memory system comprising:
a memory cell array comprising a plurality of memory cells, each memory cell comprising a phase change material changed into set and reset states depending on an amount of current supplied; and
a write driver configured to supply current corresponding to a set or reset state to a selected memory cell of the memory cell array,
wherein the write driver comprises a slow quenching unit comprising an analog circuit unit supplying slowly decreasing current to the memory cell array.

2. The phase change memory system of claim 1, wherein the write driver further comprises:
a boosting circuit unit configured to supply current up to a predetermined level to the memory cell array; and
a fast quenching unit configured to rapidly decrease the increased current.

3. The phase change memory system of claim 2, wherein the analog circuit unit comprises an inverting integrator configured to linearly decrease output voltage as time elapses.

4. The phase change memory system of claim 3, wherein the inverting integrator comprises:
an operator amplifier configured to have a grounded positive input and a negative input receiving a set command;
a resistor configured to be connected to a negative input terminal of the operation amplifier; and
a capacitor configured to be connected between the resistor and an output terminal of the boosting circuit unit.

5. The phase change memory system of claim 2, wherein output terminals of the boosting circuit unit, the slow quenching unit, and the fast quenching unit are connected to a common node.

6. The phase change memory system of claim 5, wherein the write driver further comprises a buffer circuit unit configured to generate stable current by buffering the voltage of the common node.

7. The phase change memory system of claim 6, wherein the buffer circuit unit comprises:
a buffer configured to be connected to the common node;
a converter configured to convert output voltage of the buffer into current; and
a current mirror configured to supply stabilized current to the memory cell array by mirroring output current of the converter.

8. A phase change memory system comprising:
a memory cell array comprising phase change memory cells comprising a plurality of word lines and a plurality of bit lines; and
a write driver comprising a set/reset pulse generator configured to be electrically connected to the plurality of bit lines, supply current corresponding to predetermined data to the selected phase change memory cell array of the memory cell array, and generate a pulse for generating current transmitted to the selected phase change memory cell array and a buffer circuit unit that buffers output voltage of the set/reset pulse generator,
wherein the set/reset pulse generator comprises a slow quenching unit comprising an inverting integrator.

9. The phase change memory system of claim 8, wherein the set/reset pulse generator further comprises:
a boosting circuit unit configured to supply current up to a predetermined level to the memory cell array; and
a fast quenching unit configured to be connected to an output terminal of the boosting circuit unit to rapidly decrease the increased current.

10. The phase change memory system of claim 9, wherein the slow quenching unit is configured to be connected to the output terminal of the boosting circuit unit to slowly decrease the increased current.

11. The phase change memory system of claim 10, wherein the inverting integrator comprises:
an operator amplifier comprising a grounded positive input and a negative input receiving a set command;
a resistor configured to be connected to a negative input terminal of the operation amplifier; and
a capacitor configured to be connected between the resistor and an output terminal of the boosting circuit unit,
wherein a quenching ratio of the increased current is determined depending on impedance values of the resistor and the capacitor.

12. The phase change memory system of claim 9, wherein the boosting circuit unit is configured to output predetermined voltage depending on enabling of a boosting signal.

13. The phase change memory system of claim 9, wherein the fast quenching unit comprises a transistor configured to discharge the output voltage of the boosting circuit unit by a reset command.

14. The phase change memory system of claim 8, wherein the buffer circuit unit comprises:
a buffer configured to be connected to an output terminal of the set/reset pulse generator;
a converter configured to convert output voltage of the buffer into current; and
a current mirror configured to supply stabilized current to the memory cell array by mirroring output current of the converter.

15. The phase change memory system of claim 14, wherein the buffer comprises a voltage follower configured to amplify and output input voltage.
